(19) United States
(12) Patent Application Publication
(10) Pub. No.: US 2010/0071944 A1
(43) Pub. Date: Mar. 25, 2010

(54) CHIP CAPACITOR EMBEDDED PWB

(75) Inventor: Kimitaka Endo, Yokohama (JP)

Correspondence Address: TESSERA;LERNER DAVID et al., 600 SOUTH AVENUE WEST, WESTFIELD, NJ, 07090, US

(73) Assignee: TESSERA INTERCONNECT MATERIALS, INC., San Jose, CA (US)

(21) Appl. No.: 12/519,950

(22) PCT Filed: Dec. 17, 2007
(86) PCT No.: PCT/US07/25841

§ 371 Date: Nov. 20, 2009

Related U.S. Application Data
(60) Provisional application No. 60/875,730, filed on Dec. 19, 2006.

(51) Int. Cl. H05K 1/16; H05K 3/30

(52) U.S. Cl. 174/260; 29/840

(57) ABSTRACT

A multiple wiring layer interconnection element includes capacitors or other electrical components embedded between a first exposed wiring layer and a second exposed wiring layer of the interconnection element. Internal wiring layers and are provided between exposed surfaces of the respective capacitors, the internal wiring layers being electrically insulated from the capacitors by dielectric layers. The internal wiring layers are isolated from each other by an internal dielectric layer. Conductive vias provide conductive interconnection between the two internal wiring layers. A method of fabricating a multiple wiring layer interconnection element is also provided.

### CROSS REFERENCE TO RELATED APPLICATIONS

This application claims the benefit of the filing date of U.S. Provisional Patent Application No. 60/875,730 filed Dec. 19, 2006, the disclosure of which is hereby incorporated herein by reference.

### BACKGROUND OF THE INVENTION

The present invention relates to a multiple wiring layer interconnection element for use in interconnecting a microelectronic element such as a semiconductor chip, packaged semiconductor chip and the like to another such chip or other component.

Microelectronic elements such as semiconductor chips often require dense external interconnections. Frequently, the networks of a semiconductor chip require large decoupling capacitances that are difficult to obtain on the chip. Accordingly, capacitors are sometimes mounted in close proximity to a chip for providing the necessary decoupling capacitance. In other cases, external inductors or resistors are required which are most conveniently mounted to a circuit panel to which the chip is also connected. However, it takes significant additional effort to solder discrete capacitors, inductors or resistors to a face of a chip carrier or circuit panel either before or after mounting the chip thereto. In addition, mounting such component on the same face of such chip carrier or circuit panel reduces the amount of area available for mounting the chip or packaged chip. In the case of chip carriers and circuit panels having multiple exposed wiring layers, mounting a capacitor or other component on the face of the chip carrier or circuit panel opposite the face on which the chip is mounted also takes away from area to be occupied by a chip or other device.

### SUMMARY OF THE INVENTION

In an embodiment of the present invention, a multiple wiring layer interconnection element includes a dielectric layer having a first surface and a second surface remote from said first surface, a plurality of first conductive traces exposed at said first surface, a plurality of second conductive traces exposed at said second surface, a plurality of solid metal features protruding in a direction away from said plurality of first conductive traces towards said second surface, and an electrical component having a plurality of solid metal terminals metallurgically fused directly to said plurality of first solid metal features.

In another embodiment of the present invention, a method of fabricating a multiple wiring layer interconnection element includes a) metallurgically fusing a plurality of solid metal terminals of an electrical component directly to a plurality of solid metal features protruding above a first metal layer of a first element to form a fused subassembly having an exposed surface remote from the first element, and (b) assembling with the fused subassembly (i) a dielectric layer having a first surface adjacent to the exposed surface of the fused subassembly, and (ii) a second metal layer adjacent to a second surface of the dielectric layer remote from the first surface.

### BRIEF DESCRIPTION OF THE DRAWINGS

FIG. 1 illustrates a multiple wiring layer interconnection element according to an embodiment of the invention.

FIG. 2 is a plan view of the interconnection element of FIG. 1.

FIG. 3 illustrates a plurality of conductive bumps according to an embodiment of the present invention.

FIGS. 4A-4E illustrate exemplary alternative structures for conductive bumps.

FIGS. 5A-5C illustrate an alternative process for forming an interconnection element.

FIGS. 6A-6B illustrate an alternative process for forming an interconnection element, according to another embodiment of the present invention.

FIG. 7 illustrates a subassembly conductively joined by means of conductive bumps according to an embodiment of the present invention.

FIG. 8 illustrates a joining process to join a plurality of subassemblies with a plurality of dielectric layers.

FIG. 9 illustrates an assembly resulting from joining process of FIG. 8.

FIG. 10 illustrates another stage of fabrication, in an embodiment of the present invention.

FIG. 11 illustrates an interconnection element, according to an embodiment of the present invention.

FIG. 12 illustrates an interconnection element, according to another embodiment of the present invention.

FIG. 13 illustrates a bump on metal layer structure, according to another embodiment of the present invention.

FIG. 14 is a sectional view illustrating an interconnection element, according to another embodiment of the present invention.

### DETAILED DESCRIPTION

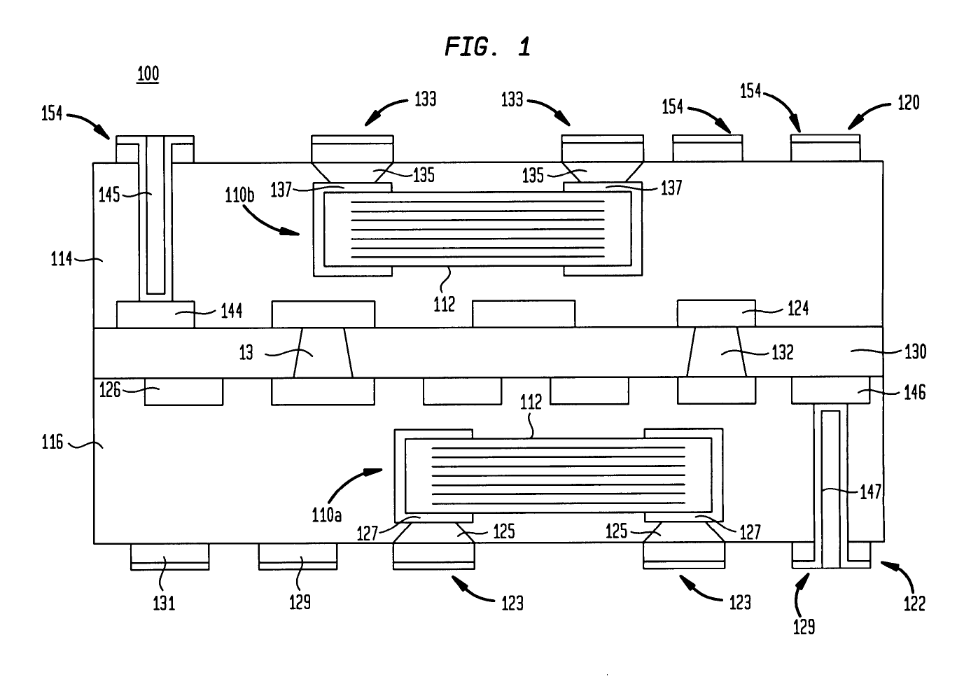

A multiple wiring layer interconnection element according to an embodiment of the invention is illustrated in FIG. 1. As shown in FIG. 1, the interconnection element 100 includes capacitors 110 or other electrical components embedded between a first exposed wiring layer 120 and a second exposed wiring layer 122 of the interconnection element 100. Each exposed wiring layer can be either relatively thin, e.g., a few (two to five) microns (μm) in thickness, have medium thickness, such as 12 μm, or 18 μm or be relatively thick, such as 35 microns or more. In addition, it is not necessary for each exposed wiring layer to have uniform thickness throughout, as some portions of the wiring layer can be thinner than others, and the two exposed wiring layers 120 and 122 need not have the same thickness. The exposed wiring layers 120, 122 desirably include a noble metal such as copper, nickel, aluminum or other metal which is at most subject only to minor surface corrosion.

Within the interconnection element 100, internal wiring layers 124 and 126 are provided between exposed surfaces 112 of the respective capacitors 110, the internal wiring layers being electrically insulated from the capacitors 110 by dielectric layers 114 and 116, respectively. The internal wiring layers 124, 126 are isolated from each other by an internal dielectric layer 130. Conductive vias 132 provide conductive interconnection between the two internal wiring layers 124, 126. Certain features such as a conductive pad 144 or trace of the internal wiring layer 124 are connected to features such as a conductive trace 154 or pad of the first exposed wiring layer 120 by a conductive via 145. Conductive vias 145 and 147 can be provided, for example, in form of plated blind vias within the dielectric layers 114, 116. Likewise, a conductive pad 146 or conductive trace of internal wiring layer 126 is connected to a trace or pad of the second exposed wiring layer 122 by another conductive via 147. Ultimately, the conductive vias 132 which connect the internal wiring layers 124, 126 provide conductive interconnection between features of the first and second exposed wiring layers 120, 122 through conductive paths including pads 144, 146 and conductive vias 145 and 147.

As further illustrated in FIG. 1, external connection to exposed terminals 127 of a lower capacitor 110a of the structure is provided through conductive traces 123 of the bottom exposed wiring layer and conductive bumps 125 which protrude therefrom. Likewise, external connection to the terminals 137 of another such capacitor 110b is provided through conductive traces 133 of an upper exposed wiring layer and bumps 135 which protrude therefrom. The capacitor terminals may include one or more noble metals such as copper, aluminum, nickel, gold, silver or tin. Desirably, the capacitor terminals 127, 137 include a higher melting temperature metal such as copper or aluminum, which may be exposed at a surface thereof, or which may be coated with another one of the aforementioned metals.

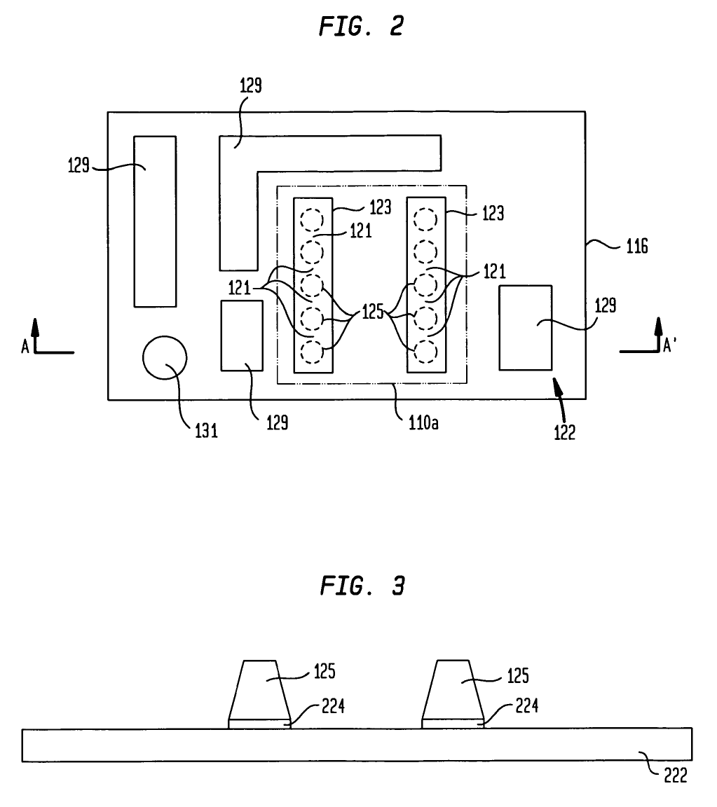

FIG. 2 is a plan view of the interconnection element illustrated in FIG. 1 looking toward the exposed second wiring layer 122 on the bottom surface thereof, where line A-A′ indicates the section view shown in FIG. 1. As illustrated in FIG. 2, traces 123 extend row-wise over the bumps 125, providing external conductive interconnection to each of the bumps. Openings between bumps are indicated at 121. While only one row of bumps 125 is illustrated in FIG. 2, several rows of bumps can be used to conductively interconnect each trace 123 to each exposed electrode 127 of the capacitor. Other traces 129 and one or more conductive pads 131 are exposed above the surface of the dielectric layer 116 at the bottom of the interconnection element.

A method of fabricating the interconnection element will now be described with reference to the following figures. As shown in FIG. 3, a plurality of conductive bumps 125 are formed to protrude above a surface of a continuous metal wiring layer 222. The bumps can be formed by a variety of different processes. Exemplary processes are described in U.S. Pat. No. 6,884,709, the disclosure of which is incorporated by reference herein. In one such process described therein, an exposed metal layer of a three-layer or more layered metal structure is etched in accordance with a photolithographically patterned photoresist layer to form bumps 125, the etching process stopping on an interior metal layer 224 of the structure. The interior metal layer 224 includes one or more metals different from that of the exposed metal layer, the interior metal layer 224 being of such composition that it is not attacked by the etchant used to etch the exposed metal layer. For example, the metal layer from which the bumps 125 are etched consists essentially of copper, the continuous metal layer 222 also consists essentially of copper, and the interior metal layer 224 consists essentially of nickel. Nickel provides good selectivity relative to copper to avoid the nickel layer from being attacked when the metal layer is etched to form bumps 125.

After forming the bumps, a different etchant is then applied to remove the interior metal layer by a process which is selective to the underlying metal layer 222. Alternatively, another way that the bumps can be formed is by electroplating, in which bumps are formed by plating a metal onto a base metal layer 222 through openings patterned in a dielectric layer such as a photoresist layer.

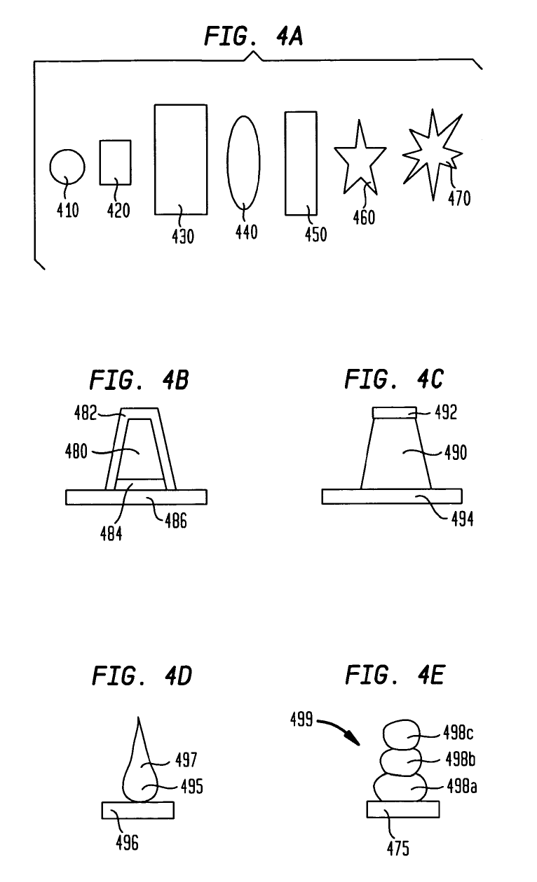

As indicated in plan view in FIG. 4A, the bumps can have a variety of different shapes and sizes. For example, when viewed from the top, the bumps can have shape which is circular 410, square or rectangular 420, rectangular and having substantial width and length (430), oval shape 440, elongated rectangular shape 450, or have a star shape, as indicated at 460 or 470. When bumps have a star shape, it may allow them to compress more easily or less easily than when other shapes are used. The height of the bumps 125 above the plane of the underlying metal layer typically ranges between about 10 microns (μm) and 1000 microns (μm) and the width ranges between about 10 microns and 2000 microns.

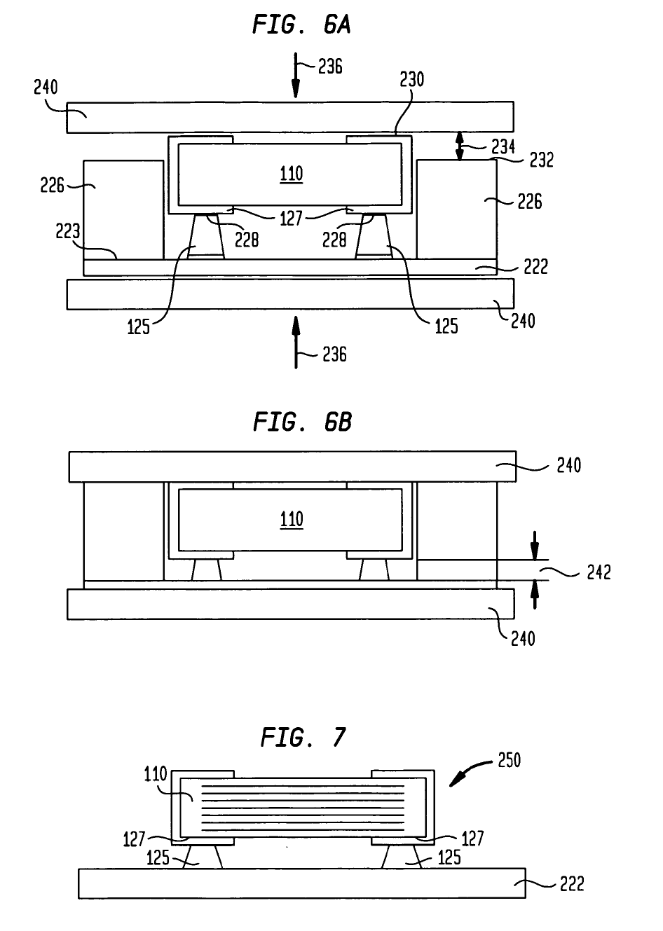

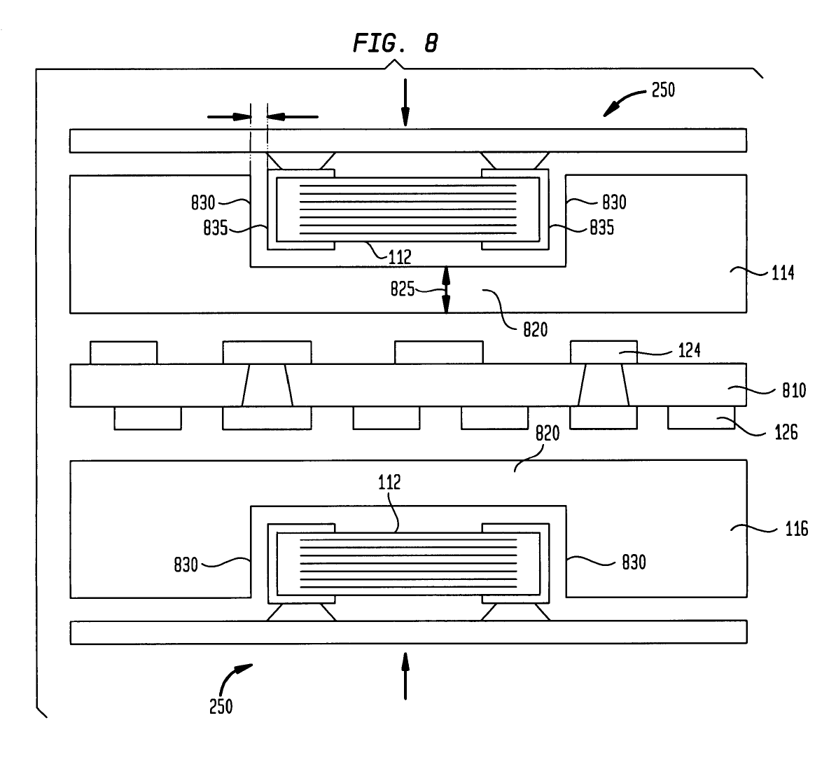

FIGS. 4B through 4E illustrate exemplary alternative structures that the bumps can take. For example, as illustrated in FIG. 4B, a bump 480 is formed by etching a first metal layer selective to an etch stop metal layer 484 which overlies a base metal layer 486, the bump 480 being coated with a second metal layer 482. The second metal layer can include the same metal as the first metal layer, one or more other metals, or a combination of a metal included in the first metal layer with another metal. In a particular embodiment, the second metal layer 482 includes a metal such as gold which is resistant to corrosion and which may also facilitate the formation of a diffusion bond between the second metal layer and a metal layer of another feature in contact therewith, as described below with reference to FIGS. 6 and 7. In another particular embodiment, the second metal layer includes a low melting temperature metal such as tin or a low melting temperature metal alloy such as solder or a eutectic composition. Additional examples of one or more metals usable as a second metal layer include nickel and aluminum.

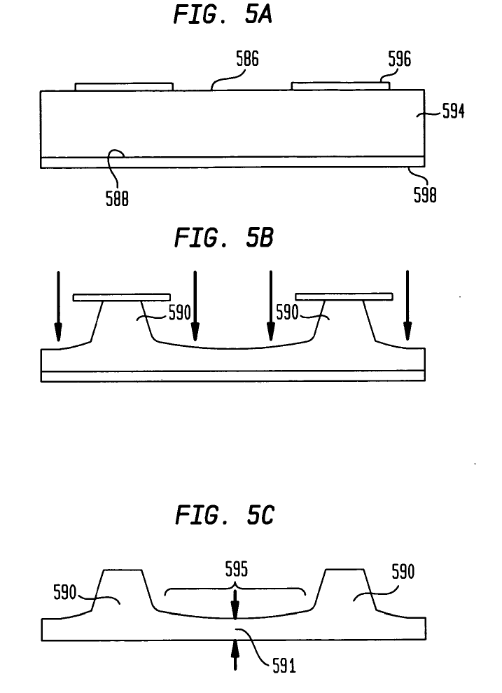

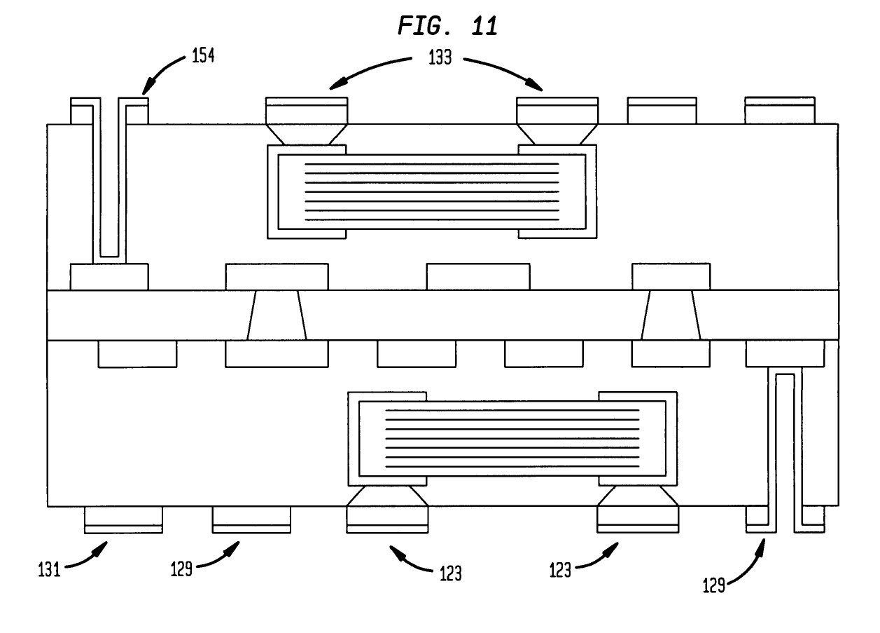

As illustrated in FIG. 4C, only the tip of a conductive bump 490 may be coated with a second metal layer 492, and the body of the conductive bump may contact the base metal layer 494 directly, without an intervening etch stop layer. Such structure can be obtained when the bumps are formed by electroplating within a cavity in a patterned mask layer (e.g., photoresist layer), followed by plating the second metal layer thereon and then removing the mask layer. An alternative process for forming a similar structure in which the middle etch stop layer is omitted is illustrated in FIGS. 5A-5C. Here, a single metal layer 594 (FIG. 5A) containing a metal or an alloy of metals will be patterned into both bumps and a wiring layer. As shown in FIG. 5A, a metal layer 594, for example, a layer of copper, has a thickness of between about 50 and about 150 microns. A rear surface 588 of the metal layer is covered with an etch-resistant coating 598. The etch-resistant coating 598 can include, for example, a photoresist or other photoimageable layer or other material which is resistant to an etchant which will be used to etch the metal layer to form bumps. After the bumps are formed, the etch-resistant coating 598 preferably should also be removable by a process which does not attack the metal layer. A front surface 586 of the metal layer is covered with a patterned mask layer 596, such as can be formed by depositing a photoresist layer and photolithographically patterning that layer. The bumps 590 are then formed by etching the base metal layer 594 in a timed manner in accordance with the mask layer. The etching is performed to an extent that the base metal layer between bumps 590 reaches a desired remaining thickness 591 (FIG. 5C). Thereafter, as illustrated in FIG. 5C, the mask layer 596 and the etch-resistant layer 598 are removed, leaving the single metal layer having bumps 590 interconnected by connecting portions 595 of the metal layer between the bumps. The connecting portions have a thickness 591 which make them patternable by an etching process used to form external wiring patterns 123, 129, 131 (FIG. 11) of the interconnection element.

Yet another way of fabricating a conductive bump 495 is illustrated in FIG. 4D in which a stud bump 495 consisting essentially of one or more metals is formed in contact with the base metal layer 496, the stud bump having a ball contacting the base metal layer and a shaft 497 protruding upward therefrom. Stud bumps typically are formed by wire-bonding equipment. Using a wire-bonding tool which supplies a wire consisting essentially of a metal such as gold, stud bumps can be formed by using the tool to melt the tip of the wire and then deposit the molten wire tip in form of a ball onto a metal surface such as base metal layer 475. The wire-bonding tool then draws back from the metal surface, forming the shaft of the stud bump, after which the wire-bonding tool clips the wire, leaving the stud bump attached to the metal surface. Wire-bonding equipment or specialized stud-bump forming equipment can be used to form similar stud bumps 495 which consist essentially of metals other than gold. As further illustrated in FIG. 4E, a conductive bump 499 can be formed by forming a series of stud bumps 498a, 498b, and 498c, one stud bump on top of another, until a desired stud bump height is reached. In this example, a relatively large height-to-width aspect ratio can be achieved, which may be desirable to keep area utilization small, if the desired height of the structure is relatively large.

As in the case of the bumps, the capacitor can have a variety of shapes. When viewed from either its top or bottom surfaces, the capacitor can appear to have square, rectangular, cylindrical or ellipsoidal shape, for example. The size of the capacitors can vary. In a particular example, a rectangular capacitor measures 3.2 millimeters (mm) in length an 1.6 millimeters (mm) in width and has a thickness of less than about 100 to 150 μm. Terminals 127 (FIG. 1) of the capacitor can consist essentially of one or more metals. Desirably, the terminals consist essentially of one or more metals selected from copper, aluminum, nickel gold, tin and silver.

Referring to FIG. 6A, after forming the metal layer 222 with protruding bumps 125 thereon, steps are performed to join the bumps 125 to the terminals 127 of the capacitor. Preferably, the bumps 125 are fused directly to the terminals 127 without the presence of a low melting temperature metal such as a solder or tin between the bumps the terminals. Preferably, in order to achieve a strong bond, the joining surfaces of the bumps and the terminals must be clean and substantially free of oxides, e.g., native oxides, before the bumps are joined to the terminals. Typically, a process characterized as a surface treatment of etching or micro- etching can be performed to remove surface oxides of noble metals such as copper, nickel, aluminum, and others, the surface etching process being performed without substantially affecting the thicknesses of the bumps or metal layer which underlies them. This cleaning process is best performed only shortly before the actual joining process. Under conditions in which the component parts are maintained after cleaning in a normal humidity environment of between about 30 to 70 percent relative humidity, the cleaning process can usually be performed up to a few hours, e.g., six hours, before the joining process without affecting the strength of the bond to be achieved between the bumps and the capacitor terminals.

As illustrated in FIG. 6A, during a process performed to join the capacitor to the bumps, a spacer structure 226 is placed on an upwardly facing surface 223 of the metal layer 222. The spacer structure can be formed of one or more materials such as polyimide, ceramic or one or more metals such as copper. The capacitor 110 is placed in an opening in the spacer structure, such that the terminals 127 overlie the top surfaces 228 of the bumps 125. At this stage of fabrication, the outer face 230 of the capacitor 110 protrudes above the outer surface 232 of the spacer structure by a certain distance. This distance 234 can be from a few percent of the height of the bumps 125 to 20 percent or more of the height of the bumps. Then, the capacitor 110, spacer structure, and metal layer with bumps thereon is inserted between a pair of plates 240 and heat and pressure are simultaneously applied to the capacitor 110 and the metal layer 223 in the directions indicated by arrows 236. As illustrated in FIG. 6B, the pressure applied to plates 240 has an effect of reducing the height of the bumps 125 to a height 242 lower than an original height of the bumps 125 as originally fabricated (FIG. 3). An exemplary range of pressure applied to during this step is between about 20 kg/cm² and about 150 kg/cm². The joining process is performed at a temperature which ranges between about 140 degrees centigrade and about 500 degrees centigrade, for example.

The joining process compresses the bumps 125 and the capacitor terminals 127 to an extent that metal from below the former top surface of the bumps and the top surfaces of the terminals come into contact and join under heat and pressure. As a result of the joining process, the height of the bumps may decrease by one micron or more. When the bumps 125 consist essentially of copper and the terminals 127 consist essentially of copper, the joints between the bumps and the terminals also consist essentially of copper, thus forming continuous copper structures including the bumps and terminals. Thereafter, as illustrated in FIG. 7, the plates and spacer structure are removed, leaving a subassembly 250 which includes the capacitor 110 having terminals 127 conductively joined to the metal layer 222 by means of conductive bumps 125.

Next, as illustrated in FIG. 8, a joining process is performed to join a plurality of subassemblies 250 with a plurality of dielectric layers 114, 116 and an intermediate dielectric element 810 including dielectric layer 130 and first and second internal wiring layers 124, 126. As depicted in FIG. 8, pressure and preferably, in addition, heat are applied to the subassemblies 250, dielectric layers 114, 116 and dielectric element 810 in directions facing the dielectric element 810 to perform this joining process. The dielectric layers 114, 116 preferably include a dielectric material which flows or deforms under heat and pressure, among which are materials such as thermoplastic polyimide, liquid crystal polyimide, resin or epoxy compositions including epoxy-glass structures, e.g., prepregs and the like, and ceramic materials, among others. Desirably, the portion 820 of each dielectric layer, for example, contacting the exposed surface 112 of the capacitor has a thickness of about 10 microns (μm) or less. Desirably, each interior wall 830 of the dielectric layer is initially spaced from an adjacent edge 835 of the capacitor, e.g., capacitor 110a, by a distance of 50 μm, although the initial spacing can be made shorter or longer, depending on the material of which the dielectric layer is made.

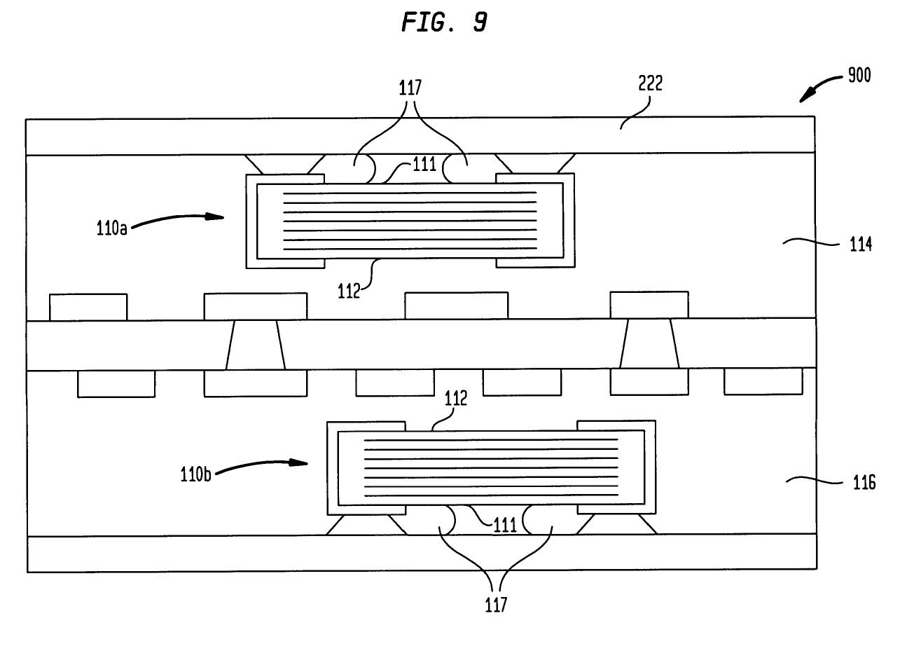

FIG. 9 illustrates an assembly 900 which results from this joining process, in which the previously exposed surfaces 112 of capacitors 110a and 110b become buried within respective dielectric layers 114, 116. Some amount of dielectric material of the dielectric layers 114, 116 may be squeezed through openings 121 (FIG. 2) between adjacent bumps 125 to provide a layer of insulating material between the inner surfaces 111 of the capacitors and the metal layers 222.

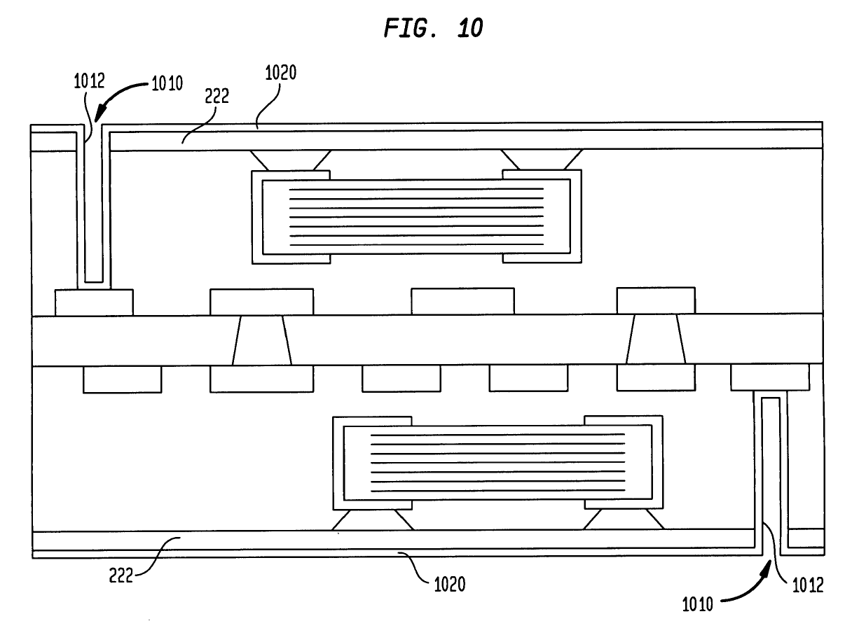

Referring to FIG. 10, in a subsequent stage of fabrication, conductive vias 1010 are formed which extend inwardly from the outer metal layers 222 of the assembly to conductive pads 144, 146 provided therefor in the interior metal layers. The blind vias in the dielectric layers 114, 116 can be formed by a process such as, for example, mechanical drilling or hammering, e.g., via ultrasonic or megasonic means or by laser drilling, among others. The blind vias are then plated to form conductive vias 1010, such as by a process of electroless deposition followed by electrolytic deposition. In a particular embodiment when the exposed metal layers 222 consist essentially of copper, the conductive vias desirably include a layer 1012 of copper inside the vias as the exposed conductive layer inside the vias. As a result of electroplating the metal layers 1012 within the vias 1010, plated metal layers 1020 are also formed which overlie the metal layers 222.

Thereafter, as illustrated in FIG. 11, the exterior metal layers (which include the plated metal layers and layers 222) are patterned into conductive traces 123, 129, 133, conductive pads 131, 154, or both. The exterior metal layers can be patterned, for example by photolithographically patterning a photoresist layer, followed by transferring the patterns in the photoresist layer to the exterior metal layers by an etch process. Desirably, such etch process is conducted in a selective manner which does not attack the dielectric layers in a substantial way.

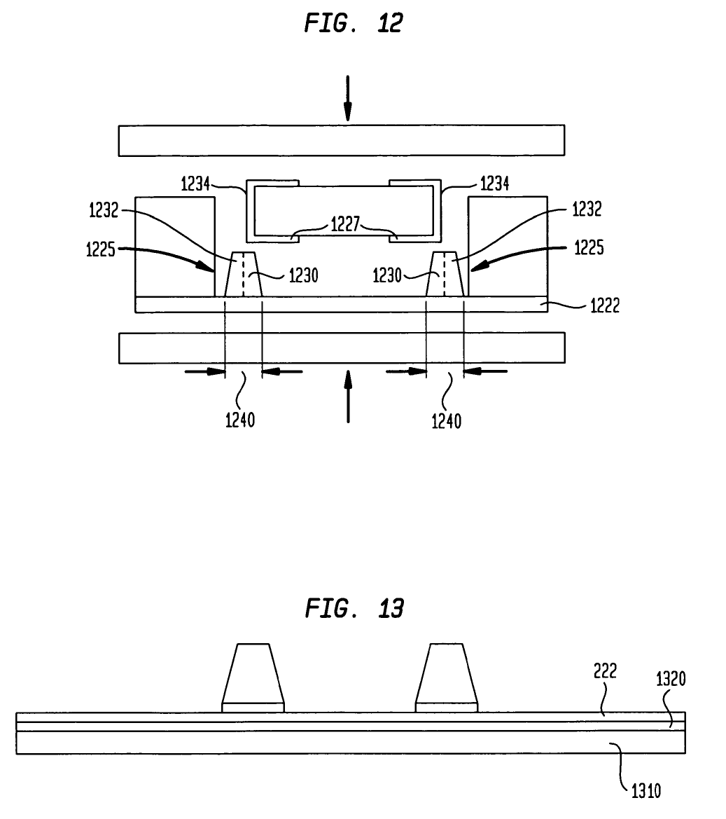

A number of variations of the above-described embodiments can be made. In one such variation (FIG. 12), bumps have substantial width 1240 extending in lateral directions, such that the conductive features on the metal layer may be in form of laterally extending conductive rails 1225. At least some of the conductive bumps 1225 connected to metal layer 1222 are aligned with edges 1230 of the capacitor terminals 1227. By making the rails sufficiently wide to assure alignment with the capacitor terminals 1227, portions 1230 of the rails 1225 can be aligned with the terminals, while other portions 1232 of the rails are not aligned with the terminals. When heat and pressure are then applied to the structure, the aligned portions 1230 of the rails 1225 deform relative to the non-aligned portions such that the joint between the capacitor terminals and the rails extends at least to the vertical edges 1234 of the capacitor terminals, and may extend onto the vertical edges 1234 themselves.

A particular embodiment (FIG. 13) concerns a variation of the bump on metal layer structure described above with reference to FIG. 3. When metal layer 222 is particularly thin, e.g., less than 10 microns in thickness, an additional carrier layer 1310 can be provided underlying the metal layer 222, such carrier layer having either a dielectric or metallic composition, and such carrier layer desirably being temporarily affixed to the metal layer 222, such as by way of an adhesive layer 1320. Desirably, when an adhesive layer 1320 is provided, the adhesive layer is peelable, etchable, or otherwise removable by subsequent processing performed after processing is performed through a stage as shown and described above with reference to FIG. 9 or FIG. 10.

In yet another alternative embodiment, in place of metal layer 222, a dielectric carrier layer can be provided. Bumps formed by plating or etching in accordance with one of the processes described above with reference to FIG. 3 contact the dielectric carrier layer itself and are supported thereby. In this case, at the stage of fabrication illustrated in FIG. 9, openings in the carrier layer aligned with the bumps can be patterned by etching and external contacts can then be provided within the openings, such as by a plating process. In another example, the carrier layers can be completely removed from the exterior surfaces of the dielectric layers 114, 116, leaving the bumps themselves in place as external contacts. In another example, with exterior surfaces of the bumps exposed after complete removal of the carrier layers, electroless plating followed by electroplating can be used to form conductive traces and conductive pads extending on the exterior surfaces of the dielectric layers 114, 116.

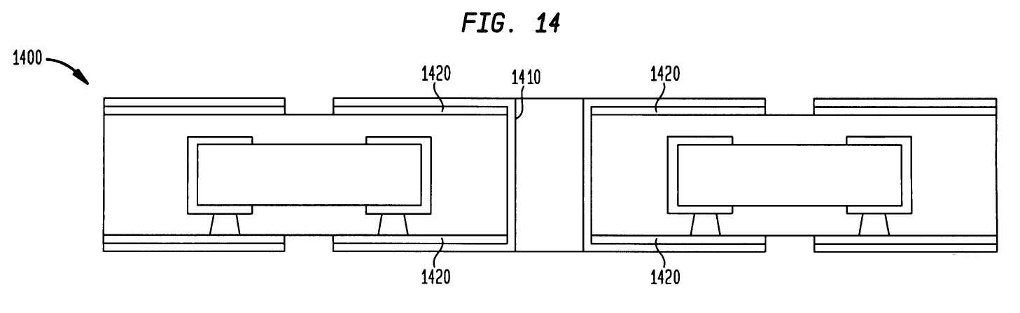

FIG. 14 is a sectional view illustrating a variation of the above-described embodiment of the invention in which the intermediate dielectric element and internal wiring layers of the interconnection element 1400 are eliminated. In addition, a plated through hole 1410 provides conductive interconnection between the wiring layers 1420 exposed at exterior surfaces of the multi-layer interconnection element. Processing used to fabricate the interconnection element is similar to that described above with reference to FIGS. 3 through 11. However, in this variation, the intermediate dielectric element 810 having internal wiring layers 1124, 126 thereon is eliminated and the capacitors are laterally separated from each other, unlike the case shown in FIG. 1, in which the capacitors are aligned in a direction of a thickness of the interconnection element 100.

In another variation, another electrical component such as an inductor and resistor is joined to bumps internally within the interconnection element in place of a capacitor as described above. Alternatively, a microelectronic element including one or more capacitors, inductors, resistors, or a combination of such devices is joined to bumps internally within the interconnection element in place of a capacitor as described above. In yet another variation, a semiconductor microelectronic element has contacts joined to the bumps internally within the interconnection element in the place of a capacitor as described above.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention.

1. A multiple wiring layer interconnection element, comprising:
a dielectric layer having a first surface and a second surface remote from said first surface;
a plurality of first conductive traces exposed at said first surface;
a plurality of second conductive traces exposed at said second surface;
a plurality of solid metal features protruding in a direction away from said plurality of first conductive traces towards said second surface; and
an electrical component having a plurality of solid metal terminals metallurgically fused directly to said plurality of solid metal features.

2. The multiple wiring layer interconnection element as claimed in claim 1, wherein said solid metal terminals consist essentially of a first metal composition, said solid metal features consist essentially of a second metal composition, and an interfacial region where said solid metal terminals and said solid metal features are fused consists essentially of a third composition, said first, second and third compositions being essentially the same.

3. The multiple wiring layer interconnection element as claimed in claim 2, wherein each of said first and second metals is selected from the group consisting of noble metals and aluminum.

4. The multiple wiring layer interconnection element as claimed in claim 2, wherein each of said first and second metal compositions consists essentially of copper.

5. The multiple wiring layer interconnection element as claimed in claim 2, wherein each of said first and second metal compositions consists essentially of aluminum.

6. The multiple wiring layer interconnection element as claimed in claim 1, wherein said first solid metal features have a first composition including a first metal exposed at exterior surfaces thereof, said solid metal terminals have a second composition including a second metal exposed at exterior surfaces thereof, and an interfacial region between said first solid metal features and said solid metal terminals has a third composition, said third composition including said first metal in solid mixture with said second metal.

7. The multiple wiring layer interconnection element as claimed in claim 6, wherein each of said first and second metals is selected from the group consisting of noble metals and aluminum.

8. The multiple wiring layer interconnection element as claimed in claim 6, wherein at least one of said first and second metals consists essentially of a single metal selected from the group consisting of nickel and gold.

9. The multiple wiring layer interconnection element as claimed in claim 1, wherein said electrical component is disposed wholly between said plurality of first conductive traces and said plurality of second conductive traces.

10. The multiple wiring layer interconnection element as claimed in claim 1, wherein said electrical component includes a discrete capacitor, and said plurality of solid metal terminals include first and second terminals for applying first and second different electrical potentials to said discrete capacitor.

11. The multiple wiring layer interconnection element as claimed in claim 1, wherein said electrical component includes a discrete resistor, and said plurality of solid metal terminals include first and second terminals for applying first and second different electrical potentials to said discrete resistor.

12. The multiple wiring layer interconnection element as claimed in claim 1, wherein said electrical component includes a discrete inductor, and said plurality of solid metal terminals include first and second terminals for receiving first and second different electrical potentials.

13. The multiple wiring layer interconnection element as claimed in claim 1, wherein said electrical component includes a semiconductor chip having a plurality of active devices thereon, and said plurality of solid metal terminals include first and second terminals for receiving first and second different electrical potentials.

14. The multiple wiring layer interconnection element as claimed in claim 1, wherein said plurality of solid metal features include a plurality of solid metal bumps, each of said solid metal bumps consisting essentially of one or more metals selected from the group consisting of noble metals and aluminum.

15. The multiple wiring layer interconnection element as claimed in claim 1, wherein said plurality of solid metal bumps have shape selected from the group consisting of pyramidal, frustum-shaped and conic.

16. The multiple wiring layer interconnection element as claimed in claim 1, wherein said plurality of solid metal bumps have height less than about 100 microns.

17. The multiple wiring layer interconnection element as claimed in claim 1, wherein said plurality of solid metal features includes a plurality of elongated solid metal rails extending lengthwise in a direction parallel to inner surfaces of said first conductive traces, each of said solid metal rails consisting essentially of one or more metals selected from the group consisting of noble metals and aluminum.

18. The multiple wiring layer interconnection element as claimed in claim 1, wherein said plurality of solid metal rails have height less than about 100 microns.

19. The multiple wiring layer interconnection element as claimed in claim 1, wherein said plurality of solid metal features are fused to said plurality of solid metal terminals via diffusion bonds.

20. An assembly including the multiple wiring layer interconnection element as claimed in claim 1 further comprising exposed external terminals connected to at least one of said plurality of first conductive traces or said plurality of second conductive traces, said exposed external terminals being conductively bonded to a plurality of contacts of a microelectronic element.

21. The assembly as claimed in claim 20, wherein said multiple wiring layer interconnection element includes a circuit panel and said microelectronic element includes a semiconductor chip.

22. The assembly as claimed in claim 20, wherein said multiple wiring layer interconnection element includes a chip carrier and said microelectronic element includes a semiconductor chip.

23. A method of fabricating a multiple wiring layer interconnection element, comprising:
(a) metallurgically fusing a plurality of solid metal terminals of an electrical component directly to a plurality of solid metal features protruding above a first metal layer of a first element to form a fused subassembly having an exposed surface remote from the first element; and
(b) assembling with the fused subassembly (i) a dielectric layer having a first surface adjacent to the exposed surface of the fused subassembly, and (ii) a second metal layer adjacent to a second surface of the dielectric layer remote from the first surface.

24. The fabrication method as claimed in claim 23, further comprising at least one of patterning the first metal layer into a plurality of first conductive traces, or patterning the second metal layer into a plurality of second conductive traces.

25. The fabrication method as claimed in claim 24, wherein the step (a) includes removing dielectric films when present from exposed surfaces of the plurality of solid first metal features and plurality of solid first metal terminals and applying heat and pressure to the first element and the electrical component until the plurality of first metal terminals fuse to the plurality of first metal features.

26. The fabrication method as claimed in claim 25, wherein the heat and the pressure are applied thermosonically.

27. The fabrication method as claimed in claim 25, wherein the heat and the pressure are applied ultrasonically.

28. The fabrication method as claimed in claim 23, further comprising forming the plurality of first metal features by plating a first metal into openings in a dielectric mask layer.

29. The fabrication method as claimed in claim 23, further comprising forming the plurality of first metal features by etching exposed portions of a third metal layer overlying the first metal layer in accordance with mask patterns overlying the third metal layer.

30. The fabrication method as claimed in claim 23, wherein said solid metal terminals consist essentially of a first metal composition, said first solid metal features consist essentially of a second metal composition, and an interfacial region where said solid metal terminals and said solid metal features are fused consists essentially of a third composition, said first, second and third compositions being essentially the same.

31. The fabrication method as claimed in claim 23, wherein said first solid metal features have a first composition including a first metal exposed at exterior surfaces thereof, said solid metal terminals have a second composition including a second metal exposed at exterior surfaces thereof, and an interfacial region between said first solid metal features and said solid metal terminals has a third composition, said third composition including said first metal in solid mixture with said second metal.
